(19) United States
(12) Patent Application Publication
(10) Pub. No.: US 2020/0411298 A1
(43) Pub. Date: Dec. 31, 2020

(54) APPARATUS AND METHOD FOR TREATING SUBSTRATE

(71) Applicant: SEMES CO., LTD., Cheonan-si (KR)

(72) Inventors: Byeung Geon JEON, Seoul (KR); Hyun-Jin KIM, Daegu (KR); Kiseong YOUN, Cheonan-si (KR); Hyo Seong SEONG, Masan-si (KR); Jong-Hwan AN, Yongin-si (KR)

(73) Assignee: SEMES CO., LTD., Cheonan-si (KR)

(21) Appl. No.: 16/913,128

(22) Filed: Jun. 26, 2020

(30) Foreign Application Priority Data
Jun. 27, 2019 (KR) 10-2019-0076766

(51) Int. Cl. H01J 37/32; H01L 21/3065

(52) U.S. Cl. CPC H01J 37/32935; H01J 37/32082; H01J 2237/334; H01L 21/3065; H01J 37/3244; H01J 37/32724

(57) ABSTRACT

An apparatus for treating a substrate includes a substrate support unit including a support plate that supports a substrate and a heating unit that controls temperature of the substrate. The heating unit includes a plurality of heating members in different regions of the support plate, a heater power source that applies power to the plurality of heating members, a filter that prevents coupling between the plurality of heating members and an RF power source, and a detection unit that is provided between the plurality of heating members and the filter and that detects plasma characteristics for the respective regions of the support plate.

### CROSS-REFERENCE TO RELATED APPLICATIONS

A claim for priority under 35 U.S.C. § 119 is made to Korean Patent Application No. 10-2019-0076766 filed on Jun. 27, 2019, in the Korean Intellectual Property Office, the entire contents of which are hereby incorporated by reference.

### BACKGROUND

Embodiments of the inventive concept described herein relate to an apparatus and method for treating a substrate, and more particularly, relate to a substrate treating apparatus and method for detecting plasma characteristics for respective regions of a support plate.

To manufacture semiconductor elements, desired patterns are formed on a substrate by performing various processes, such as photolithography, etching, ashing, ion implantation, thin-film deposition, cleaning, and the like, on the substrate. Among these processes, the etching process is a process of removing a selected region of a film formed on the substrate, and wet etching or dry etching is used.

An etching apparatus using plasma is used for dry etching. In general, to form plasma, the etching apparatus forms an electromagnetic field in the interior space of a chamber, and the electromagnetic field excites a process gas in the chamber into a plasma state.

Plasma refers to an ionized gaseous state of matter containing ions, electrons, and radicals. The plasma is generated by heating a neutral gas to a very high temperature or subjecting the neutral gas to a strong electric field or an RF electromagnetic field. A semiconductor element manufacturing process performs an etching process using plasma. The etching process is performed by collision of ion particles contained in the plasma with a substrate.

Recently, as a process is more precisely controlled, it is important to detect plasma characteristics in a chamber. In the related art, to identify the plasma characteristics in the chamber, a VI sensor is mounted on an RF rod to monitor the plasma characteristics in the chamber. Therefore, only RF parameter values coupled to the RF rod may be identified, and plasma characteristics for respective regions over an electrostatic chuck cannot be detected.

### SUMMARY

Embodiments of the inventive concept provide a substrate treating apparatus and method for detecting plasma characteristics for respective regions of a support plate.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, an apparatus for treating a substrate includes a chamber having a treatment space therein, a substrate support unit that supports the substrate in the treatment space, a gas supply unit that supplies a gas into the treatment space, and a plasma generation unit including an RF power source that applies RF power, wherein the plasma generation unit generates plasma from the gas by using the RF power. The substrate support unit includes a support plate that supports the substrate and a heating unit that controls temperature of the substrate. The heating unit includes a plurality of heating members disposed in different regions of the support plate, a heater power source that applies power to the plurality of heating members, a filter that prevents coupling between the plurality of heating members and the RF power source, and a detection unit that is provided between the plurality of heating members and the filter and that detects plasma characteristics for the respective regions of the support plate.

The detection unit may include a measurement member that measures voltages and currents in the regions in which the plurality of heating members are located, respectively, and a control member that detects the plasma characteristics for the respective regions of the support plate, based on the voltages and the currents in the regions.

The detection unit may further include a display member that displays the voltages and the currents for the respective regions of the support plate.

The display member may be a digitizer.

The plasma generation unit may uniformly control plasma density in an entire region of the support plate, based on the plasma characteristics for the respective regions of the support plate.

According to an exemplary embodiment, an apparatus for treating a substrate includes a chamber having a treatment space therein, a substrate support unit that supports the substrate in the treatment space, a gas supply unit that supplies a gas into the treatment space, and a plasma generation unit including an RF power source that applies RF power, wherein the plasma generation unit generates plasma from the gas by using the RF power. The substrate support unit includes a support plate that supports the substrate and a heating unit that controls temperature of the substrate. The heating unit includes a plurality of heating members disposed in a plurality of regions of the support plate, a heater power source that applies power to the plurality of heating members, a filter that prevents coupling between the plurality of heating members and the RF power source, and a detection unit that monitors a plurality of RF parameters for the plurality of regions of the support plate.

According to an exemplary embodiment, provided is a substrate treating method of a substrate treating apparatus including a filter that prevents coupling between a plurality of heating members and an RF power source, wherein the plurality of heating members are disposed in different regions of a support plate that supports a substrate, and the RF power source applies RF power to the support plate. The substrate treating method includes measuring voltages and currents in the regions of the support plate by using a measurement member provided between the plurality of heating members and the filter and detecting plasma characteristics for the respective regions of the support plate by using the voltages and the currents measured.

Plasma density in an entire region of the support plate may be uniformly controlled based on the plasma characteristics for the respective regions of the support plate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a substrate treating apparatus according to an embodiment of the inventive concept;

FIG. 2 is a detailed sectional view illustrating a substrate support unit in the substrate treating apparatus of FIG. 1;

FIG. 3 is a view illustrating a substrate support unit according to another embodiment of the inventive concept;

FIG. 4 is a circuit diagram illustrating a detection unit and a filter according to an embodiment of the inventive concept; and

FIG. 5 is a flowchart illustrating a substrate treating method according to an embodiment of the inventive concept.

### DETAILED DESCRIPTION

Other advantages and features of the inventive concept, and implementation methods thereof will be clarified through the following embodiments to be described in detail with reference to the accompanying drawings. The inventive concept may, however, be embodied in different forms and should not be construed as being limited to the embodiments set forth herein. Rather, these embodiments are provided so that this disclosure is thorough and complete and fully conveys the scope of the inventive concept to a person skilled in the art to which the inventive concept pertains. Further, the inventive concept is only defined by the appended claims.

Even though not defined, all terms used herein (including technical or scientific terms) have the same meanings as those generally accepted by general technologies in the related art to which the inventive concept pertains. The terms defined in general dictionaries may be construed as having the same meanings as those used in the related art and/or a text of the present application and even when some terms are not clearly defined, they should not be construed as being conceptual or excessively formal.

Terms used herein are only for description of embodiments and are not intended to limit the inventive concept. As used herein, the singular forms are intended to include the plural forms as well, unless context clearly indicates otherwise. It will be further understood that the terms “comprise” and/or “comprising” used herein specify the presence of stated features or components, but do not preclude the presence or addition of one or more other features or components. In the specification, the term “and/or” indicates each of listed components or various combinations thereof.

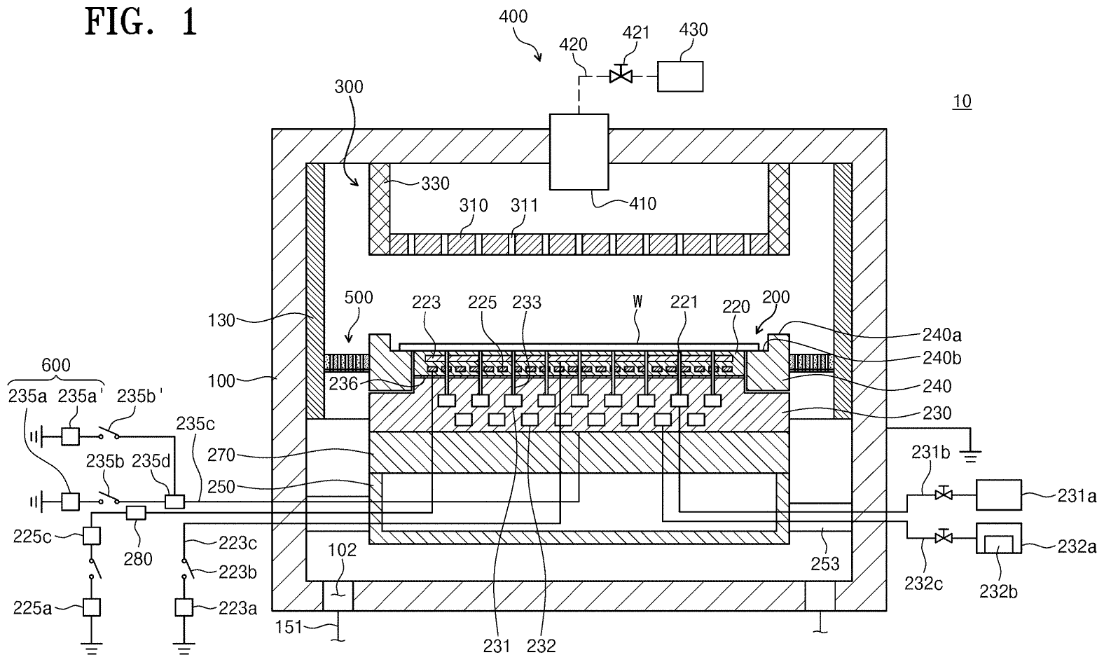

FIG. 1 is a sectional view illustrating a substrate treating apparatus 10 according to an embodiment of the inventive concept.

Referring to FIG. 1, the substrate treating apparatus 10 treats a substrate W using plasma. For example, the substrate treating apparatus 10 may perform an etching process on the substrate W. The substrate treating apparatus 10 may include the chamber 100, the substrate support unit 200, a showerhead 300, a gas supply unit 400, a baffle unit 500, and a plasma generation unit 600.

The chamber 100 may have a treatment space therein in which a substrate treating process is performed. The chamber 100 may have the treatment space therein and may be provided in an enclosed shape. The chamber 100 may be formed of a metallic material. According to an embodiment, the chamber 100 may be formed of an aluminum material. The chamber 100 may be grounded. The chamber 100 may have an exhaust hole 102 formed in the bottom thereof. The exhaust hole 102 may be connected with an exhaust line 151. Reaction byproducts generated in the substrate treating process and gases staying in the interior space of the chamber 100 may be released to the outside through the exhaust line 151. The pressure in the chamber 100 may be reduced to a predetermined pressure by the exhaust process.

According to an embodiment, a liner 130 may be provided inside the chamber 100. The liner 130 may have a cylindrical shape that is open at the top and the bottom. The liner 130 may make contact with an inner surface of the chamber 100. The liner 130 may protect the inner wall of the chamber 100 to prevent the inner wall of the chamber 100 from being damaged by arc discharge. Furthermore, the liner 130 may prevent impurities generated during the substrate treating process from being deposited on the inner wall of the chamber 100. Selectively, the liner 130 may not be provided.

The substrate support unit 200 may be located inside the chamber 100. The substrate support unit 200 may support the substrate W. The substrate support unit 200 may include an electrostatic chuck 210 that clamps the substrate W using an electrostatic force. Alternatively, the substrate support unit 200 may support the substrate W in various manners such as mechanical clamping. Hereinafter, the substrate support unit 200 including the electrostatic chuck 210 will be described.

The substrate support unit 200 may include the electrostatic chuck 210, a lower cover 250, and a plate 270. Inside the chamber 100, the substrate support unit 200 is located to be spaced apart upward from the bottom of the chamber 100.

The electrostatic chuck 210 may include a dielectric plate 220, a body 230, and a ring assembly 240. The dielectric plate 220 may be located at the top of the electrostatic chuck 210. The dielectric plate 220 may be formed of a dielectric substance in a circular plate shape. The substrate W may be placed on an upper surface of the dielectric plate 220. The upper surface of the dielectric plate 220 may have a smaller radius than the substrate W. An edge region of the substrate W may be located outside the dielectric plate 220.

The dielectric plate 220 may include a first electrode 223, a heating member 225, and a first supply passage 221 inside. The first supply passage 221 may extend from the upper surface of the dielectric plate 210 to a lower surface thereof. A plurality of first supply passages 221 may be formed to be spaced apart from each other and may serve as passages through which a heat transfer medium is supplied to a bottom surface of the substrate W.

The first electrode 223 may be electrically connected with a first power source 223a. The first power source 223a may include a direct current (DC) power source. A switch 223b may be installed between the first electrode 223 and the first power source 223a. The first electrode 223 may be electrically connected with the first power source 223a by turning on/off the switch 223b. When the switch 223b is turned on, DC current may be applied to the first electrode 223. An electrostatic force may act between the first electrode 223 and the substrate W by the current applied to the first electrode 223, and the substrate W may be clamped to the dielectric plate 220 by the electrostatic force.

The heating member 225 may be located under the first electrode 223. The heating member 225 may be electrically connected with a heater power source 225a. The heater power source 225a may be an alternating current (AC) power source. The heating member 225 may generate heat by resisting electric current applied by the heater power source 225a. The generated heat may be transferred to the substrate W through the dielectric plate 220. The substrate W may be maintained at a predetermined temperature by the heat generated from the heating member 225. The heating member 225 may include a spiral coil.

The body 230 may be located under the dielectric plate 220. The lower surface of the dielectric plate 220 and an upper surface of the body 230 may be bonded together by an adhesive 236. The body 230 may be formed of an aluminum material. The upper surface of the body 230 may have a step such that a central region of the upper surface of the body 230 is located in a higher position than an edge region of the upper surface of the body 230. The central region of the upper surface of the body 230 may have an area corresponding to the lower surface of the dielectric plate 220 and may be bonded to the lower surface of the dielectric plate 220. The body 230 may have a first circulation passage 231, a second circulation passage 232, and a second supply passage 233 formed therein.

The first circulation passage 231 may serve as a passage through which the heat transfer medium circulates. The first circulation passage 231 may be formed in a spiral shape inside the body 230. Alternatively, the first circulation passage 231 may be implemented with ring-shaped passages that have different radii and that are concentric with one another. The first circulation passages 231 may be connected together. The first circulation passages 231 may be formed at the same height.

The second circulation passage 232 may serve as a passage through which a cooling fluid circulates. The second circulation passage 232 may be formed in a spiral shape inside the body 230. Alternatively, the second circulation passage 232 may be implemented with ring-shaped passages that have different radii and that are concentric with one another. The second circulation passages 232 may be connected together. The second circulation passages 232 may have a larger cross-sectional area than the first circulation passages 231. The second circulation passages 232 may be formed at the same height. The second circulation passages 232 may be located under the first circulation passages 231.

The second supply passage 233 may extend upward from the first circulation passages 231 to the upper surface of the body 230. As many second supply passages 233 as the first supply passages 221 may be provided. The second supply passages 233 may connect the first circulation passages 231 and the first supply passages 221.

The first circulation passages 231 may be connected with a heat transfer medium reservoir 231a through a heat transfer medium supply line 231b. The heat transfer medium may be stored in the heat transfer medium reservoir 231a. The heat transfer medium may include an inert gas. According to an embodiment, the heat transfer medium may include a helium (He) gas. The helium gas may be supplied into the first circulation passages 231 through the heat transfer medium supply line 231b and then supplied to the bottom surface of the substrate W via the second supply passages 233 and the first supply passages 221. The helium gas serves as a medium through which heat transferred from plasma to the substrate W is transferred to the electrostatic chuck 210.

The second circulation passages 232 may be connected with a cooling fluid reservoir 232a through a cooling fluid supply line 232c. The cooling fluid may be stored in the cooling fluid reservoir 232a. The cooling fluid reservoir 232a may include a cooler 232b therein. The cooler 232b may cool the cooling fluid to a predetermined temperature. Alternatively, the cooler 232b may be installed on the cooling fluid supply line 232c. The cooling fluid supplied into the second circulation passages 232 through the cooling fluid supply line 232c may cool the body 230 while circulating along the second circulation passages 232. The body 230, while being cooled, may cool the dielectric plate 220 and the substrate W together to maintain the substrate W at a predetermined temperature.

The body 230 may include a metal plate. According to an embodiment, the entire body 230 may be implemented with a metal plate. The body 230 may be electrically connected with a third power source 235a and a fourth power source 235a′. The third power source 235a and the fourth power source 235a′ may be high-frequency power sources that generate high-frequency power. According to an embodiment, frequencies applied by the third power source 235a and the fourth power source 235a′ may differ from each other. According to an embodiment, the third power source 235a may apply a higher frequency than the fourth power source 235a′. The high-frequency power sources may be RF power sources. The body 230 may receive RF power from the third power source 235a and the fourth power source 235a′. Due to this, the body 230 may function as an electrode. The body 230 may be connected with the third power source 235a and the fourth power source 235a′ through a power line 235c. A matcher 235d may be disposed between the body 230 and the third and fourth power sources 235a and 235a′. The matcher 235d may perform control to match impedance between the body 230 and the third and fourth power sources 235a and 235a′.

The ring assembly 240 has a ring shape. The ring assembly 240 surrounds the periphery of the dielectric plate 220. The ring assembly 240 supports the edge region of the substrate W. According to an embodiment, the ring assembly 240 has a focus ring 240b and an insulating ring 240a. The focus ring 240b surrounds the dielectric plate 220 and concentrates plasma on the substrate W. The insulating ring 240a surrounds the focus ring 240b. Selectively, the ring assembly 240 may include an edge ring (not illustrated) that is brought into close contact with the periphery of the focus ring 240b to prevent a side surface of the dielectric plate 220 from being damaged by plasma. Unlike the above description, the structure of the ring assembly 240 may be changed in various ways.

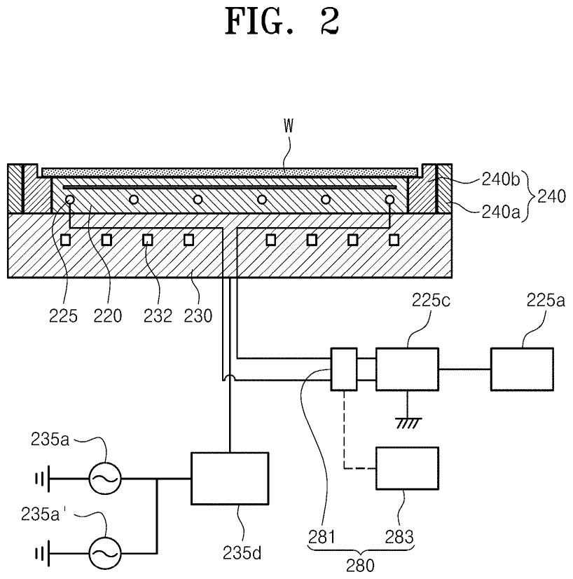

FIG. 2 is a detailed sectional view illustrating the substrate support unit in the substrate treating apparatus of FIG. 1.

Referring to FIG. 2, a plurality of heating members 255 are provided in different regions of the dielectric plate 220, and power is applied to the plurality of heating members 225 by the heater power source 225a. A filter 225c for preventing coupling between the plurality of heating members 225 and the RF power sources 235a and 235a′ is provided between the plurality of heating members 225 and the heater power source 225a. The matcher 235d may be connected between the RF power sources 235a and 235a′ and the body 230 and may perform control to match impedance between the RF power sources 235a and 235a′ and the body 230.

The plurality of heating members 225 may be implemented with a heating wire. Furthermore, a detection unit 280 for detecting plasma characteristics for the respective regions of the dielectric plate 220 may be provided between the plurality of heating members 225 and the filter 225c. Here, the plurality of heating members 225, the heater power source 225a, the filter 225c, and the detection unit 280 may constitute a heating unit.

The detection unit 280 includes a measurement member 281 and a control member 283. The measurement member 281 may be provided between the plurality of heating members 225 and the filter 225c and may measure voltages and currents in the plurality of regions of the dielectric plate 220 in which the plurality of heating members 225 are located, respectively. For example, the measurement member 281 may be a voltage measurement sensor or a current measurement sensor. Based on the voltages and the currents in the plurality of regions of the dielectric plate 220 that are measured by the measurement member 281, the control member 283 may detect the plasma characteristics for the respective regions of the dielectric plate 220. More specifically, based on the voltages and the currents in the plurality of regions of the dielectric plate 220 that are measured by the measurement member 281, the control member 283 may detect or monitor an RF parameter associated with the plasma characteristics. For example, the RF parameter may include at least one of a parameter relating to an RF pulse signal of each of the plurality of regions, RF parameter power formation, RF power, voltage, current, phase, or impedance. Furthermore, the detection unit 280 may include a display member (not illustrated) that displays the voltages and the currents in the plurality of regions of the dielectric plate 220 that are measured by the measurement member 281. For example, the display member (not illustrated) may be a digitizer.

The plasma generation unit 600 may uniformly control plasma density in the entire region of the dielectric plate 220 by using the plasma characteristics for the respective regions of the dielectric plate 220 that are detected by the detection unit 280.

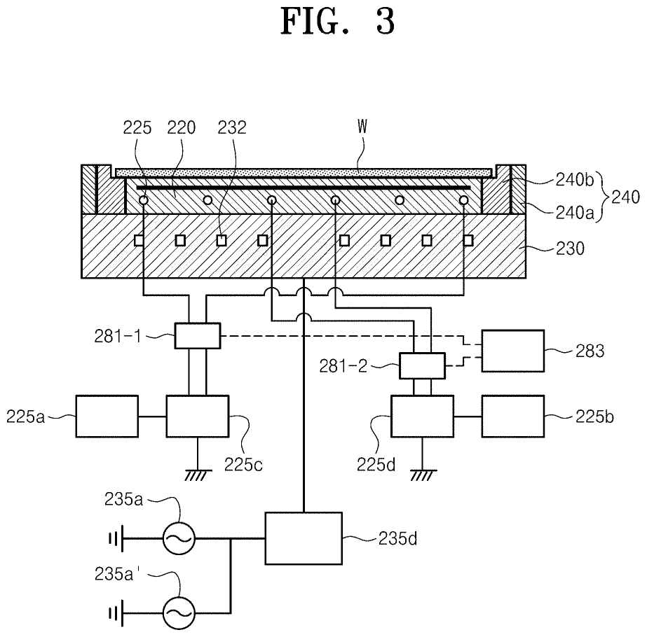

Referring to FIG. 3, a plurality of heating members 225 may be provided in different regions of a dielectric plate 220, and a plurality of heater power sources 225a and 225b and a plurality of filters 225c and 225d may be provided for the plurality of heating members 225, respectively. Furthermore, measurement members 281-1 and 281-2 may be provided between the plurality of heating members 225 and the plurality of filters 225c and 225d. A control member 283 may detect plasma characteristics for the respective regions of the dielectric plate 220 by using voltages and currents in the plurality of regions of the dielectric plate 220 that are measured by the plurality of measurement members 281-1 and 281-2.

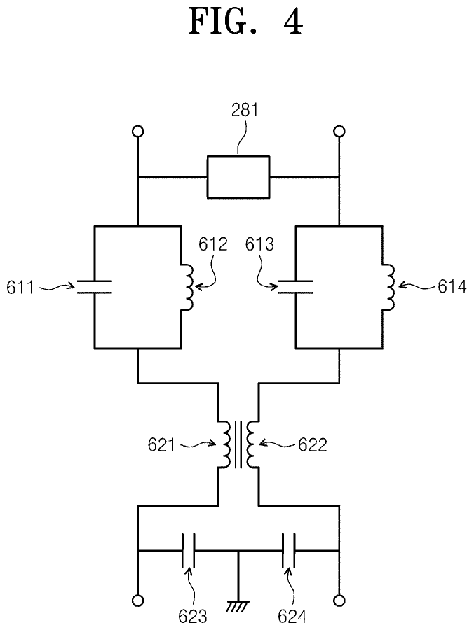

Referring to FIG. 4, the filter 225c may include a parallel circuit of a first capacitor 611 and a first inductor 612 and a parallel circuit of a second capacitor 613 and a second inductor 614, and the parallel circuits may be connected to different terminals. The measurement member 281 may be provided between the parallel circuit of the first capacitor 611 and the first inductor 612 and the parallel circuit of the second capacitor 613 and the second inductor 614. Furthermore, the filter 225c may include a circuit in which a third inductor 621 and a fourth inductor 622 are inductively coupled with each other and a circuit in which a third capacitor 623 and a fourth capacitor 624 are connected with each other in parallel.

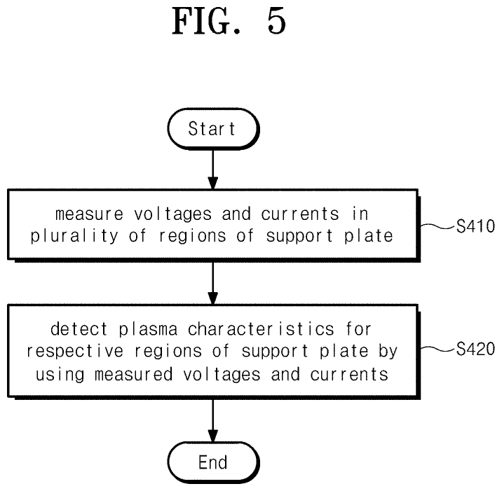

FIG. 5 is a flowchart illustrating a substrate treating method according to an embodiment of the inventive concept.

Referring to FIG. 5, first, voltages and currents are measured in a plurality of regions of a support plate by using a measurement member provided between a plurality of heating members and a filter (S140). Next, plasma characteristics for the respective regions of the support plate are detected by using the measured voltages and currents (S420). In addition, plasma density in the entire region of the support plate may be uniformly controlled by using the detected plasma characteristics for the respective regions.

As described above, according to the various embodiments of the inventive concept, the plasma characteristics for the respective regions of the support plate may be easily detected.

Hereinabove, it has been exemplified that an etching process is performed by using plasma. Without being limited thereto, however, the substrate treating process may be applied to various substrate treating processes (e.g., a deposition process, an ashing process, a cleaning process, and the like) that use plasma. Furthermore, it has been exemplified that the plasma generation unit is implemented with a capacitively coupled plasma source. However, the plasma generation unit may be implemented with an inductively coupled plasma (ICP) source. The ICP source may include an antenna.

As described above, according to the various embodiments of the inventive concept, the substrate treating apparatus and method may easily detect plasma characteristics for respective regions of a support plate.

Effects of the inventive concept are not limited to the aforementioned effects, and any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. For example, the components illustrated in the embodiments of the inventive concept can be implemented in a distributed manner. Likewise, the components described to be distributed can be implemented in a combined manner. Accordingly, the spirit and scope of the inventive concept should be determined by the technical idea of the claims, and it should be understood that the spirit and scope of the inventive concept is not limited to the literal description of the claims, but actually extends to the category of equivalents of technical value.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a chamber having a treatment space therein;
a substrate support unit configured to support the substrate in the treatment space;
a gas supply unit configured to supply a gas into the treatment space; and
a plasma generation unit including an RF power source configured to apply RF power, the plasma generation unit being configured to generate plasma from the gas by using the RF power,
wherein the substrate support unit includes:
a support plate configured to support the substrate; and
a heating unit configured to control temperature of the substrate, and
wherein the heating unit includes:
a plurality of heating members disposed in different regions of the support plate;
a heater power source configured to apply power to the plurality of heating members;
a filter configured to prevent coupling between the plurality of heating members and the RF power source; and
a detection unit provided between the plurality of heating members and the filter and configured to detect plasma characteristics for the respective regions of the support plate.

2. The apparatus of claim 1, wherein the detection unit includes:
a measurement member configured to measure voltages and currents in the regions in which the plurality of heating members are located, respectively; and
a control member configured to detect the plasma characteristics for the respective regions of the support plate, based on the voltages and the currents in the regions.

3. The apparatus of claim 2, wherein the detection unit further includes a display member configured to display the voltages and the currents for the respective regions of the support plate.

4. The apparatus of claim 3, wherein the display member is a digitizer.

5. The apparatus of claim 2, wherein the plasma generation unit uniformly controls plasma density in an entire region of the support plate, based on the plasma characteristics for the respective regions of the support plate.

6. An apparatus for treating a substrate, the apparatus comprising:
a chamber having a treatment space therein;
a substrate support unit configured to support the substrate in the treatment space;
a gas supply unit configured to supply a gas into the treatment space; and
a plasma generation unit including an RF power source configured to apply RF power, the plasma generation unit being configured to generate plasma from the gas by using the RF power,
wherein the substrate support unit includes:
a support plate configured to support the substrate; and
a heating unit configured to control temperature of the substrate, and
wherein the heating unit includes:
a plurality of heating members disposed in a plurality of regions of the support plate;
a heater power source configured to apply power to the plurality of heating members;
a filter configured to prevent coupling between the plurality of heating members and the RF power source; and
a detection unit configured to monitor a plurality of RF parameters for the plurality of regions of the support plate.

7. The apparatus of claim 6, wherein the detection unit includes:
a plurality of measurement members configured to measure a plurality of voltages and a plurality of currents for the plurality of regions of the support plate; and
a control member configured to detect the plurality of RF parameters for the plurality of regions, based on the plurality of voltages and the plurality of currents.

8. The apparatus of claim 7, wherein each of the plurality of RF parameters includes at least one of voltage, current, RF power, phase, or impedance.

9. The apparatus of claim 7, wherein the detection unit further includes a display member configured to display the plurality of voltages and the plurality of currents for the plurality of regions of the support plate.

10. The apparatus of claim 9, wherein the display member is a digitizer.

11-12. (canceled)
